(19) United States
(12) Patent Application Publication
(10) Pub. No.: US 2022/0171370 A1
(43) Pub. Date: Jun. 2, 2022

(54) HIGH DENSITY, CONTROLLED INTEGRATED CIRCUITS FACTORY

(71) Applicant: Lam Research Corporation, Fremont, CA (US)

(72) Inventors: Thorsten LILL, Kalaheo, HI (US); Mariusch GREGOR, Gilroy, CA (US); Candi KRISTOFFERSEN, San Jose, CA (US)

(21) Appl. No.: 17/601,669

(22) PCT Filed: Apr. 16, 2020
(86) PCT No.: PCT/US2020/028470

§ 371 Date: Oct. 5, 2021

Related U.S. Application Data
(60) Provisional application No. 62/835,984, filed on Apr. 18, 2019.

(51) Int. Cl. G05B 19/418; H01L 21/67; H01L 21/677

(52) U.S. Cl. CPC G05B 19/41825; G05B 19/4189; G05B 2219/45031; H01L 21/67727; H01L 21/67733; H01L 21/67276

(57) ABSTRACT

A high density, controlled integrated circuits factory having process modules occupying approximately two-thirds of the factory floor space with the remaining one-third of the factory floor space being used for servicing the process modules and for loading and unloading wafers to and from the process modules. A subfloor is provided below the factory floor to allow service lifts to travel across the factory. Service lifts can be raised to the factory floor level to service process modules. Overhead lines are also provided over the process modules to transport service items as well as wafers across the factory.

### RELATED APPLICATIONS

This application claims priority to and the benefit of U.S. Provisional Application No. 62/835,984, filed on Apr. 18, 2019, which is hereby incorporated herein by reference for all purposes.

### BACKGROUND

The disclosure relates to integrated circuits (IC) processing. More specifically, the disclosure relates to integrating IC processing chambers into a factory that is as dense as possible and controls the environment.

Current IC manufacturing platforms were designed for humans to operate the tools (e.g., processing chambers) used in forming semiconductor devices. The current design results in wasted space in the factory, as the semiconductor wafers are often transferred between atmosphere and vacuum. Currently, overhead space is only used in front of the tools and corridors are provided between systems to move large systems.

Current factories transfer wafers in atmosphere or N₂ between systems. The systems themselves typically are operating in vacuum. Some systems, such as wet clean systems, operate in atmosphere or N₂. Thus, wafers are often being transferred between atmosphere and vacuum, which is time, energy, and space consuming.

Thus, as IC processing has evolved to have less human interaction, it would be desirable to have a factory design that is efficient, with as little wasted space as possible.

### SUMMARY

According to an embodiment, an integrated circuit manufacturing factory is provided. The factory includes a plurality of process modules for processing integrated circuits positioned on a floor of the factory and unoccupied space of the floor of the factory. The plurality of process modules occupies more than half of the floor of the factory and the unoccupied space is less than half of the floor of the factory.

According to another embodiment, an integrated circuit manufacturing factory is provided. The factory includes a plurality of process modules for processing integrated circuits and unoccupied space of the floor of the factory. The plurality of process modules is positioned on a floor of the factory and the unoccupied space includes a plurality of service areas positioned on the floor of the factory and a plurality of load areas positioned on the floor of the factory.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1A is a schematic top view of an example of a typical IC manufacturing factory.

FIG. 1B shows a typical process tool in the IC manufacturing factory shown in FIG. 1A.

FIG. 2A is a schematic top view of a cleanroom level of an efficient IC manufacturing factory in accordance with an embodiment.

FIG. 2B shows an exemplary service area in more detail.

FIG. 2C shows an exemplary load area in more detail.

FIG. 3A is a cross sectional view of an embodiment of a mobile vacuum transfer module.

FIG. 3B is a cross-sectional view of another embodiment of a mobile vacuum transfer module.

FIG. 3C is a top view of an embodiment of a mobile vacuum transfer module.

FIG. 4 is a schematic top view of an embodiment of a subfloor level of the factory.

FIG. 5 is a cross-sectional view of an embodiment of the factory.

### DETAILED DESCRIPTION OF EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

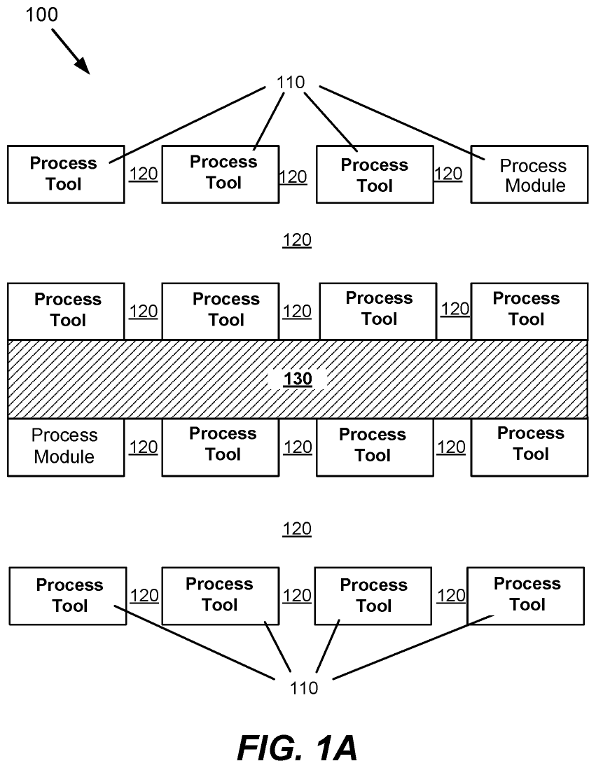

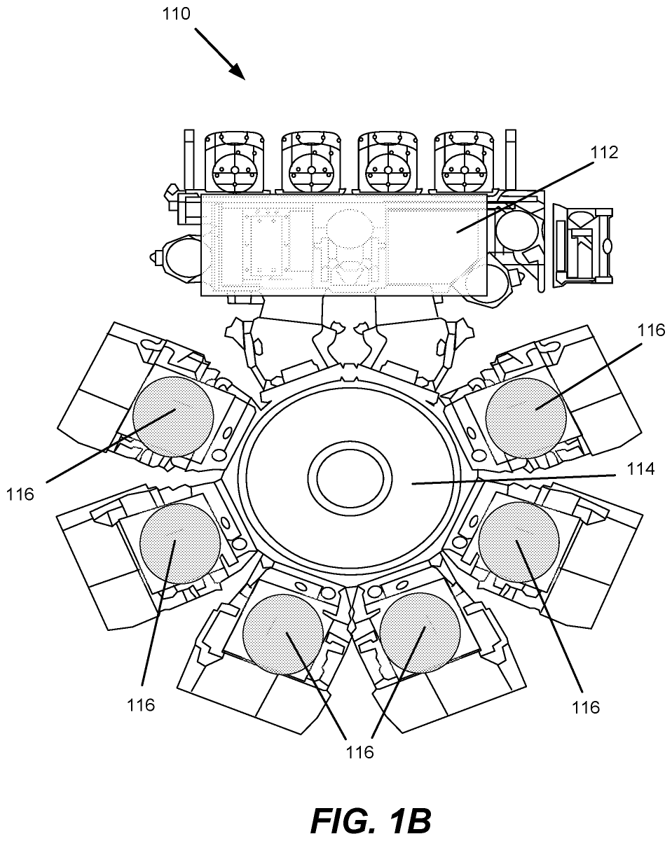

FIG. 1A is a schematic top view of an example of a typical IC manufacturing factory 100. As shown in FIG. 1A, the current IC factory is designed for humans to operate the process tools 110 in the factory. A typical process tool 110 is shown in FIG. 1B and can include vacuum transfer modules (VTM), enclosed front end modules (EFEM), and process modules for performing semiconductor processing steps, such as chemical mechanical planarization, film deposition (e.g., physical vapor deposition (PVD), chemical vapor deposition (CVD), electrocleposition), polishing, etching, patterning or lithography, photoresist spin coating, ion implantation, diffusion, and oxidation for dielectric film growth. As shown in FIG. 1B, a process tool 110 includes an EFEM 112, which is a transfer module for transferring wafers from atmosphere to vacuum, as well as a VTM 114, which is a transfer module for transferring wafers between vacuum and a process chamber 116.

The typical IC factory has corridors provided between the process tools 110 in order to provide space to bring the process tools 110 out if necessary. As shown in FIG. 1A, there is a great deal of wasted floor space devoted to corridors between the process tools 110, including service areas 120 that provide space for servicing the process tools 110 and load and tool operator areas 130 for human operators to operate the process tools 110 as well as transfer wafers into and out of process chambers. Thus, there is a great deal of floor space that is unoccupied by process tools 110 in current IC manufacturing factories. In the embodiments of IC factories described below, there is less unoccupied floor space and separate VTMs and EFEMs that occupy floor space are also unnecessary.

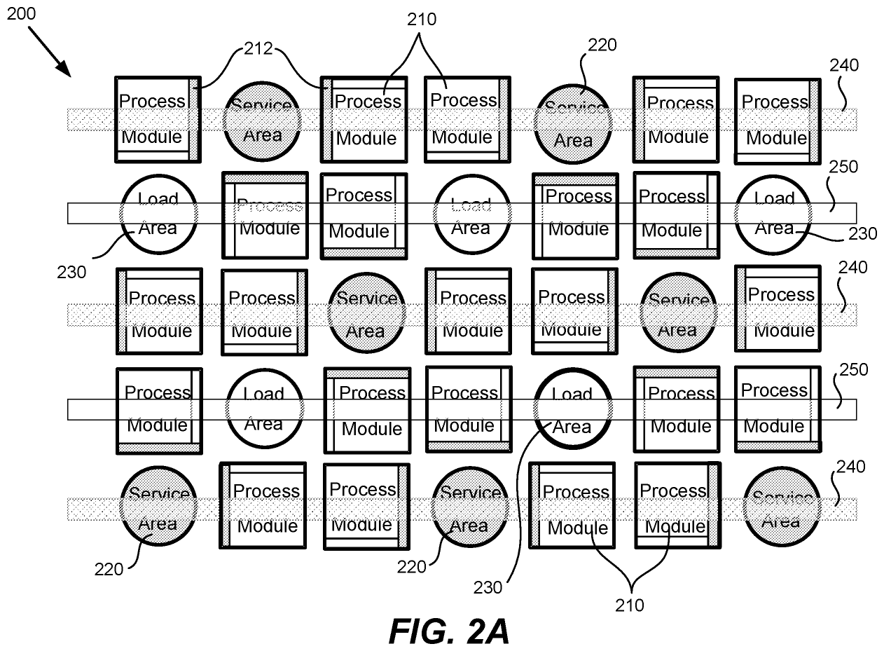

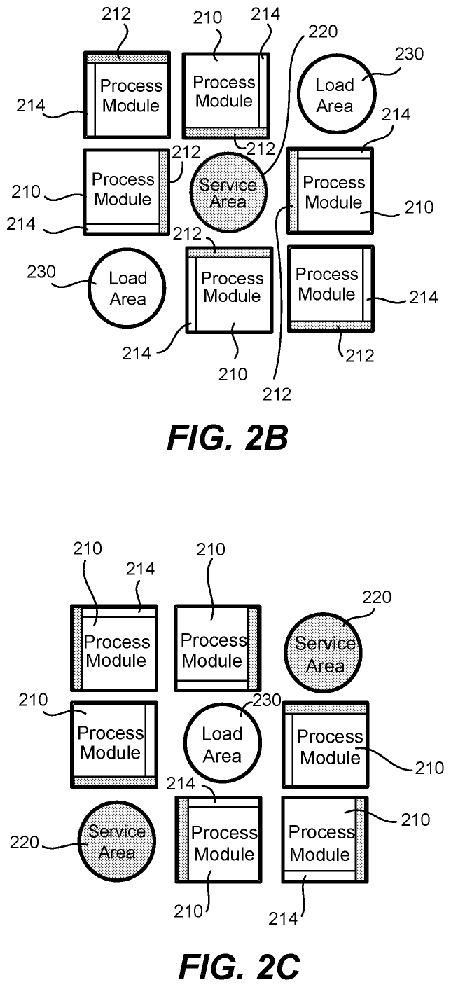

FIG. 2A is a schematic top view of a cleanroom level of an efficient IC manufacturing factory 200 in accordance with an embodiment. In the embodiments described herein, more than half of the factory floor space is occupied by IC processing modules 210 and less than half of the factory floor space is not occupied by IC processing modules 210. As shown in FIG. 2A, approximately two-thirds of the factory floor space are occupied by IC processing modules 210 and approximately one-third of the factory floor space is unoccupied to allow for space for servicing the processing modules 210 and for loading and unloading of wafers to and from the IC processing modules 210. The unoccupied floor space includes service areas 220 (for service of process modules 210) and load areas 230 (for loading and unloading wafers to and from process modules 210).

As shown in FIG. 2A, the service area 220 and load area 230 are on different sides of each process module. One service area 220 can be provided for servicing more than one process module 210. In the embodiment shown in FIG. 2A, each service area 220 is provided for servicing at least two process modules 210. Some service areas 220 can service up to four process modules 210. Similarly, one load area 230 can be provided for loading and unloading wafers to and from more than one process module 210. In the embodiment shown in FIG. 2A, each load area 230 is provided for loading and unloading wafers to and from at least two process modules 210. Some load areas 230 can be used for loading and unloading wafers to and from up to four different process modules 210.

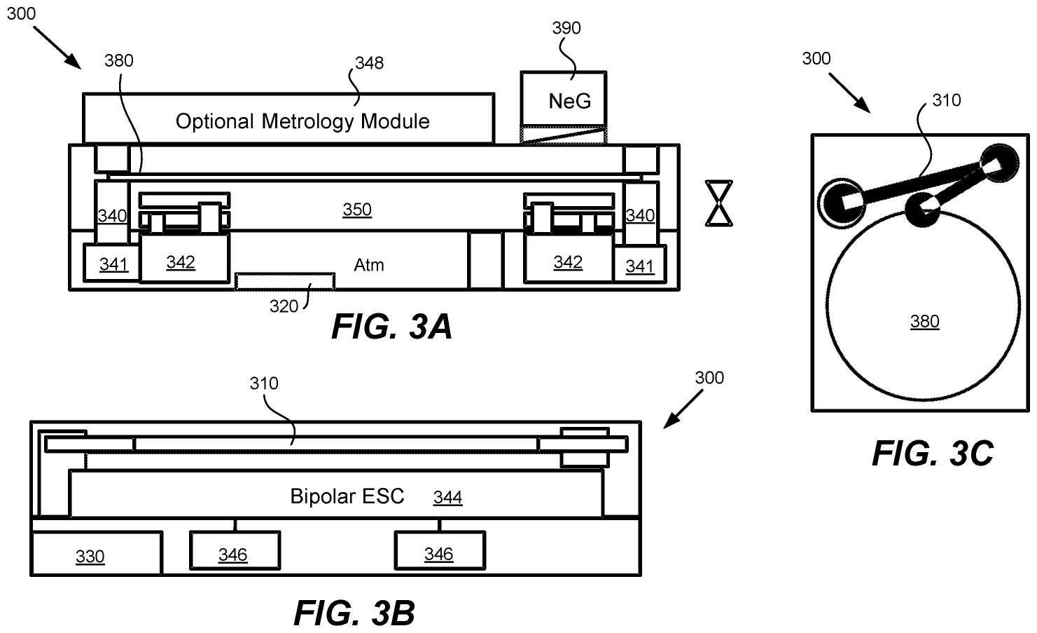

As shown in FIG. 2A, the factory 200 is also provided with overhead lines 240, 250 to allow for transfer of items across the factory over the process modules 210. According to some embodiments, the overhead lines 240, 250 are provided with rails to allow overhead transfer systems to transfer items, such as service items (e.g., spare parts) or mobile vacuum transfer modules (MVTMs) 300 (FIGS. 3A-3C), to move along the rails above the process modules 210. Service items can be transported along overhead lines 240 to a particular process module 210 that needs to be serviced. Similarly, MVTMs 300 can also be transported along overhead lines 250 to dock with a particular process module 210 to unload a wafer from the process module 210 and transfer the wafer within the controlled vacuum environment of the MVTM 300 to another process module 210, as described in more detail below. According to other embodiments, the overhead lines 240, 250 do not have rails but instead provide pathways along which drone-like devices can fly to transport service items and MVTMs 300.

As noted above, the overhead lines 240 allow for overhead transfer of service items, such as spare parts, that may be needed for servicing the process modules, and overhead lines 250 allow for overhead transfer of MVTMs 300 across the factory 200. FIGS. 3A-3C show a MVTM 300 in more detail.

The MVTM 300 is a compact mobile front opening universal pod (FOUP) that allows for transfer of a wafer 380 in a controlled vacuum environment 350, which reduces the amount of time wasted transferring wafers between vacuum and atmosphere. The MVTM 300 would allow a wafer to remain in vacuum while being transferred between process modules 210. According to an embodiment, the MVTM 300 is configured to maintain vacuum at 1 e−4 torr for at least 20 minutes.

The MVTM 300 can be transported along overhead lines 250 to arrive at a load area 230 for a particular process module 210 with which the MVTM 300 docks. As shown in FIG. 3C, the MVTM 300 includes a built-in wafer handler, such as a Selective Compliance Assembly Robot Arm or Selective Compliance Articulated Robot Arm (S CARA) robot 310 for loading a wafer into a process module 210 and unloading a wafer from a process module 210.

According to this embodiment, the MVTM 300 docks directly to a standalone process module 210. The MVTM 300 has standardized electrical and communication interfaces for interfacing with other tools in the factory, including the process modules 210. The MVTM 300 also has a standardized and automated main door and roughing pump connections to interface with the process modules 210. The electrical and communication interfaces, the wafer handler 310, and other functions of the MVTM 300 are controlled by an integrated controller 330. In some embodiments, the controller 330 can manage the temperature within the MVTM 300. Although the controller 330 is not shown in FIG. 3A, it will be understood that the embodiment of FIG. 3A can also have such a controller.

The MVTM 300 also has a wafer clamp for holding the wafer in place during transport. The wafer clamp can employ a clamping technology, such as vacuum, electrostatic, mechanical, and magnetic. The wafer clamp maintains the wafer 380 position within the MVTM 300 during transport up to the maximum allowed acceleration of the MVTM 300. FIG. 3A shows a magnetically driven wafer clamp 340 according to an embodiment, and FIG. 3B shows an electrostatic chuck (ESC) 344 according to another embodiment.

In the embodiment shown in FIG. 3A, each of the magnetically driven wafer clamps 340 is controlled by a lift 341 that is driven by a magnetically coupled drive 342 with magnetically linear bearings. In the embodiment shown in FIG. 3B, the ESC 344 is driven by the liftpin drives 346.

In some embodiments, as shown in FIG. 3A, the MVTM 300 can be provided with a self-contained battery pack 320, which can operate the MVTM 300 for purposes, such as an emergency wafer unloading. In an embodiment where the MVTM 300 is a drone-like device, the battery pack 320 can power all functions of the MVTM 300. In embodiments where the MVTM 300 moves along rails of the overhead line 250, the MVTM 300 can be powered by the overhead line 250 via standardized electrical interfaces.

In some embodiments, the MVTM 300 can also be provided with a metrology tool 348, as shown in FIG. 3A. Although the metrology tool 348 is not shown in FIG. 3B, it will be understood that the embodiment shown in FIG. 3B can also be provided with a metrology tool. In some embodiments, the MVTM 300 is also provided with a RF ID tag so that its location in the factory 200 can be tracked in the factory 200. A non-evaporable getter pump 390 is also provided in the embodiment shown in FIG. 3A.

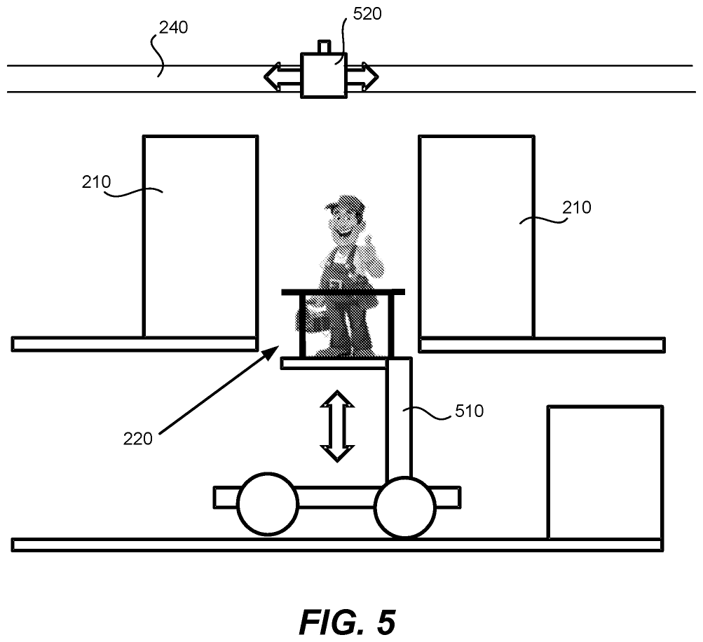

A factory 200 having a layout as described above has the densest possible layout, where wafers are loaded into and unloaded from a process module 210 at one site (load area 230), the process module 210 is serviced from a second site (service area 220), MVTMs 300 and service items are transported from above the process modules 210 and service lifts 510 (FIG. 5) are brought up from the subfloor level below. Each process module 210 is loaded and unloaded from one side and serviced from another side.

According to the illustrated embodiment, except for the service areas 220 on the edges of the factory 200, each service area 220 has four process modules 210 positioned around it. FIG. 2B shows an exemplary service area 220 in more detail. As shown in FIG. 2B, four process modules 210 are oriented and positioned surrounding the service area 220 such that the service side 212 of the process module 210 that allows for service/maintenance is facing the service area 220. Thus, each process module 210 can be serviced from an adjacent service area 220. FIG. 2B shows two additional process modules 210; however, these two process modules 210 are serviced by different service areas that are not shown in FIG. 2B. As shown in FIG. 2B, these two process modules 210 have service sides 212 that do not face the service area 220 shown in FIG. 2B.

Each process module 210 has a service side 212 and a load side 214. As shown in the illustrated embodiment, the service side 212 is positioned on a side 90 degrees from the load side 214. The service side 212 is provided on the process module 210 to allow for maintenance and service of the process module 210. The load side 214 is provided with a standardized opening configured for interfacing with the standardized opening of the MVTM 300, which is configured to dock with the load side 214.

Similarly, in the illustrated embodiment, except for the load areas 230 on the edges of the factory 200, each load area 230 has four process modules 210 positioned around it. The process modules 210 are oriented and positioned surrounding the load area 230 such that the side of the process module 210 that allows for loading and unloading of wafers is facing the load area 230. For example, a MVTM 300 can be transported along an overhead line 250 and drop down in the load area 230 in front of the process module from which it is to unload a wafer.

FIG. 2C shows an exemplary load area 230 in more detail. As shown in FIG. 2C, four process modules 210 are oriented and positioned surrounding the load area 230 such that the load side 214 of the process module 210 that allows for loading and unloading of wafers is facing the load area 230. Thus, each process module 210 can have wafers loaded or unloaded from an adjacent load area 230. FIG. 2C shows two additional process modules 210; however, the wafers of these two process modules 210 are loaded and unloaded in different load areas that are not shown in FIG. 2C. As shown in FIG. 2C, these two process modules 210 have load sides 214 that do not face the load area 230 shown in FIG. 2C.

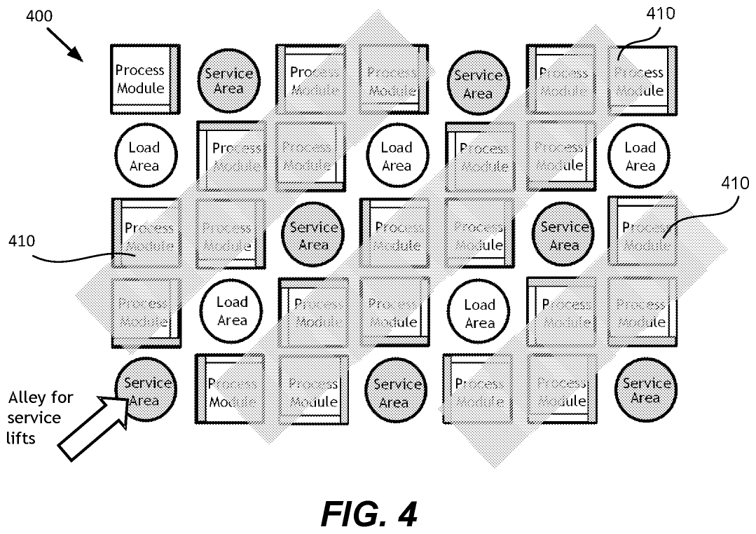

FIG. 4 is a schematic top view of an embodiment of a subfloor level 400 of the factory 200. It will be understood that the subfloor level 400 shown in FIG. 4 is below the level shown in FIG. 2A. Remote modules, such as chillers and RF generators can be positioned in diagonal remote module strips 410 on the subfloor level 400 under the process modules 210. As shown in FIG. 4, the diagonal remote module strips 410 are positioned in strips with alleys therebetween. It will be understood that the layout of the level of FIG. 2A is shown in FIG. 4 to show the positioning the remote modules relative to the process modules 210, service areas 220, and load areas 230.

As shown in FIG. 4, the alleys between the diagonal remote module strips 410 are positioned underneath the service areas 220 and load areas 230 to allow service lifts 510 (FIG. 5) to travel along the alleys to reach the service area 220. That is, service lifts 510 can travel along the alleys between the diagonal remote module strips 410 on the subfloor level and are then raised to service process modules 210 on the cleanroom level.

FIG. 5 is a cross-sectional view of an embodiment of the factory 200, showing both the cleanroom level of FIG. 2A and the subfloor level of FIG. 4. As shown in FIG. 5, a service lift 510 has been lifted from the subfloor level to the cleanroom level to allow a technician to service a process module 210. As shown in FIG. 5, there is no floor in the service areas 220 between the subfloor level and the cleanroom level to allow a ladder or service lift 510 to rise from the subfloor level to the cleanroom level to service a process module 210. Also as shown in FIG. 5, a service item 520, such as a spare part for a process module 210, can be transported via overhead line 240 across the factory 200 to a process module 210 that needs to be serviced using the spare part.

The factory 200 layout described herein has the densest possible layout, with as little wasted space as possible. The benefits of the layout described herein include lower cost using the densest possible layout due to no need for a separate VTM and EFEM. Performance is also improved as the elimination of wafer transfer between vacuum and atmosphere avoids oxidation and particle performance because of reduction of pump down and venting.

Although only a few embodiments of the invention have been described in detail, it should be appreciated that the invention may be implemented in many other forms without departing from the spirit or scope of the invention. In view of all of the foregoing, it should be apparent that the present embodiments are illustrative and not restrictive and the invention is not limited to the details given herein, but may be modified within the scope and equivalents of the appended claims.

What is claimed is:

1. An integrated circuit manufacturing factory, comprising:
a plurality of process modules for processing integrated circuits, wherein the plurality of process modules is positioned on a floor of the factory, and wherein the plurality of process modules occupies more than half of the floor of the factory; and
unoccupied space of the floor of the factory, wherein the unoccupied space is less than half of the floor of the factory.

2. The integrated circuit manufacturing factory as recited in claim 1, wherein the unoccupied space comprises a plurality of service areas positioned on the floor of the factory and a plurality of load areas positioned on the floor of the factory.

3. The integrated circuit manufacturing factory as recited in claim 2, wherein each of the process modules comprises a service side and a load side.

4. The integrated circuit manufacturing factory as recited in claim 2, wherein the service side and load side of each of the process modules is on a different side of the process module.

5. The integrated circuit manufacturing factory as recited in claim 4, wherein the service side is positioned 90 degrees from the load side.

6. The integrated circuit manufacturing factory as recited in claim 3, wherein a service area has at least two service sides facing the service area, wherein the at least two service sides comprise a first service side of a first process module and a second service side of a second process module.

7. The integrated circuit manufacturing factory as recited in claim 3, wherein a load area has at least two load sides facing the load area, wherein the at least two load sides comprise a first load side of a first process module and a second load side of a second process module.

8. The integrated circuit manufacturing factory as recited in claim 2, further comprising overhead lines across the factory, wherein the overhead lines are positioned above the process modules for transferring items across the factory.

9. The integrated circuit manufacturing factory as recited in claim 8, wherein the overhead lines comprise at least one service overhead line and at least one wafer transfer overhead line, wherein the at least one service overhead line is configured to transfer service items to and from service areas and the at least one wafer transfer overhead line is configured to transfer mobile vacuum transfer modules to and from load areas.

10. The integrated circuit manufacturing factory as recited in claim 9, wherein the mobile vacuum transfer modules are configured to dock with a process module.

11. The integrated circuit manufacturing factory as recited in claim 9, wherein each of the mobile vacuum transfer modules is configured to transport a wafer in vacuum between process modules along a wafer transfer overhead line.

12. The integrated circuit manufacturing factory as recited in claim 2, further comprising a subfloor below the floor, wherein service lifts can travel along alleys on the subfloor, the alleys positioned beneath the service areas and the load areas.

13. The integrated circuit manufacturing factory as recited in claim 12, wherein the service lifts can be raised from the subfloor to service a process module.

14. An integrated circuit manufacturing factory, comprising:
a plurality of process modules for processing integrated circuits, wherein the plurality of process modules is positioned on a floor of the factory; and
unoccupied space of the floor of the factory, wherein the unoccupied space comprises a plurality of service areas positioned on the floor of the factory and a plurality of load areas positioned on the floor of the factory.

15. The integrated circuit manufacturing factory as recited in claim 14, wherein each service area is configured for servicing at least two different process modules.

16. The integrated circuit manufacturing factory as recited in claim 15, wherein at least one service area is configured for servicing four process modules.

17. The integrated circuit manufacturing factory as recited in claim 14, wherein each load area is configured for loading and unloading wafers to and from more than one process module.

18. The integrated circuit manufacturing factory as recited in claim 17, wherein at least one load area is configured for loading and unloading wafers to and from four different process modules.

19. The integrated circuit manufacturing factory as recited in claim 14, further comprising overhead lines across the factory, wherein the overhead lines are positioned above the process modules for transferring items across the factory and the overhead lines comprise at least one service overhead line and at least one wafer transfer overhead line, wherein the at least one service overhead line is configured to transfer service items to and from service areas and the at least one wafer transfer overhead line is configured to transfer mobile vacuum transfer modules to and from load areas.

20. The integrated circuit manufacturing factory as recited in claim 19, wherein the overhead lines comprise either rails or drone pathways.

21. The integrated circuit manufacturing factory as recited in claim 14, further comprising:
at least one service lift; and
a subfloor below the floor, the subfloor comprising alleys along which the at least one service lift can travel, wherein the alleys are positioned beneath the service areas and the load areas and the at least one service lift can be raised from the subfloor to service a process module.
